(19) United States
(12) Patent Application Publication
(10) Pub. No.: US 2020/0357326 A1
(43) Pub. Date: Nov. 12, 2020

(54) GATE DRIVER CIRCUIT AND DRIVING METHOD OF TOUCH DISPLAY PANEL

(71) Applicant: HANNSTAR DISPLAY CORPORATION, Taipei City (TW)

(72) Inventor: Ya-Wen Lee, Tainan City (TW)

(21) Appl. No.: 16/862,521

(22) Filed: Apr. 29, 2020

(30) Foreign Application Priority Data
May 6, 2019 (CN) 201910372594.1

(51) Int. Cl. G09G 3/20; G06F 3/14; G06F 3/147; G06F 3/041; G06F 3/044; H03K 17/96

(52) U.S. Cl. CPC G09G 3/2092; G06F 3/1407; G06F 3/147; G09G 2310/0286; G06F 3/044; H03K 17/962; G06F 3/04166

(57) ABSTRACT

The present invention provides a gate driver circuit used for driving a touch display panel. The gate driver circuit includes a plurality of shift registers, each of the shift registers receives a forward input signal and a backward input signal, and the shift registers sequentially output a plurality of scan signals to the touch display panel according to the forward input signal and the backward input signal, wherein the forward input signal and the backward input signal provided to the shift registers are in phase at least twice in a frame time.

### CROSS REFERENCE TO RELATED APPLICATION

This application claims priority of China Application No. 201910372594.1, filed on May 6, 2019. The entirety of the above-mentioned patent application is incorporated by reference herein and made a part of this specification.

### BACKGROUND OF THE INVENTION

### 1. Field of the Invention

The present invention relates to a gate driver circuit and a driving method of a touch display panel, and more particularly, to a gate driver circuit and a driving method of a touch display panel that can improve the image displaying quality.

### 2. Description of the Prior Art

Touch devices have been widely applied to display panels of all kinds of electronic products to form touch display devices. This allows users to communicate directly with electronic products instead of using traditional input devices such as a keyboard or mouse. The volume of electronic products can thereby be reduced and the convenience of communication between human and computer can be enhanced. In recent years, the industry has been devoted to developing an in-cell touch display device, wherein the touch device is integrated into the display panel to minimize the volume of the touch display device.

In the conventional in-cell touch display device, one of the timing allocation methods is inserting a plurality of touch sensing periods into the frame time of displaying every image. However, some transistors in the shift registers of the gate driver circuit are set to have certain voltage levels for a long time during touch sensing periods, and the leakage currents of these transistors will cause distortion of scan signals output by the shift registers, resulting in the phenomenon that the display image has horizontal stripes.

### SUMMARY OF THE INVENTION

The present invention provides a gate driver circuit and a driving method of a touch display panel to solve the above technical problem. The gate driver circuit and the driving method of the touch display panel can suppress the distortion of scan signals output by shift registers and improve image displaying quality.

To solve the above technical problem, the present invention provides a gate driver circuit used for driving a touch display panel. The gate driver circuit includes a plurality of shift registers, each of the shift registers receives a forward input signal and a backward input signal, and the shift registers sequentially output a plurality of scan signals to the touch display panel according to the forward input signal and the backward input signal, wherein the forward input signal and the backward input signal provided to the shift registers are in phase at least twice in a frame time.

The present invention further provides a driving method of a touch display panel, it includes providing a gate driver circuit including a plurality of shift registers, wherein each of the shift registers receives a forward input signal and a backward input signal, and the shift registers sequentially output a plurality of scan signals to the touch display panel according to the forward input signal and the backward input signal. The forward input signal and the backward input signal provided to the shift registers are set to be in phase at least twice in a frame time.

In the gate driver circuit and the driving method of the touch display panel of the present invention, the forward input signal and the backward input signal are set to be in phase in the touch period (i.e., the first period). For example, the forward input signal and the backward input signal are designed to have the identical voltage level. Therefore, the leakage current of the thin film transistor in the shift register can be reduced to avoid the distortion of the scan signal output by the shift register and the phenomenon that the display image has horizontal stripes, thereby improving the image display quality.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a top view of a touch portion of a touch display panel according to a first embodiment of the present invention.

FIG. 2 is a schematic diagram illustrating a top view of a display portion of the touch display panel according to the first embodiment of the present invention.

FIG. 3 is a schematic diagram illustrating a gate driver circuit according to the first embodiment of the present invention.

FIG. 4 is an equivalent circuit diagram of an ith-level shift register in the gate driver circuit shown in FIG. 3.

FIG. 5 is a timing diagram of the gate driver circuit of FIG. 3 in a forward scanning mode.

FIG. 6 is a schematic diagram of signals received by a common electrode according to the first embodiment of the present invention.

FIG. 7 is a timing diagram of a gate driver circuit in a backward scanning mode according to a second embodiment of the present invention.

FIG. 8 is a timing diagram of a gate driver circuit in a forward scanning mode according to a third embodiment of the present invention.

### DETAILED DESCRIPTION

To provide a better understanding of the present invention to those skilled in the technology, embodiments will be detailed as follows. The embodiments of the present invention are illustrated in the accompanying drawings to elaborate on the contents and effects to be achieved. It should be noted that the drawings are simplified schematics, and therefore show only the components and combinations associated with the present invention, so as to provide a clearer description of the basic architecture or method of implementation. The components would be complex in reality. In addition, for ease of explanation, the components shown in the drawings may not represent their actual number, shape, and dimensions; details can be adjusted according to design requirements.

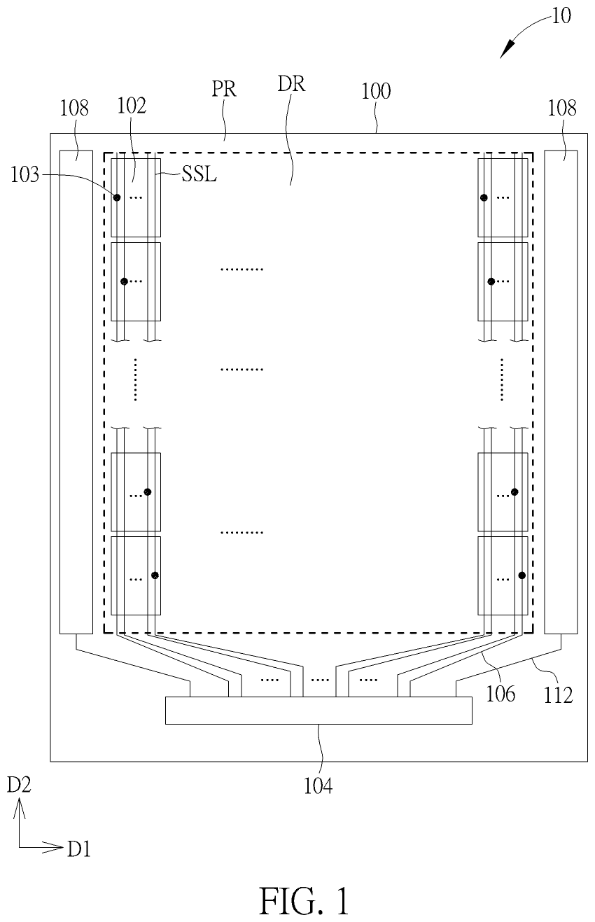

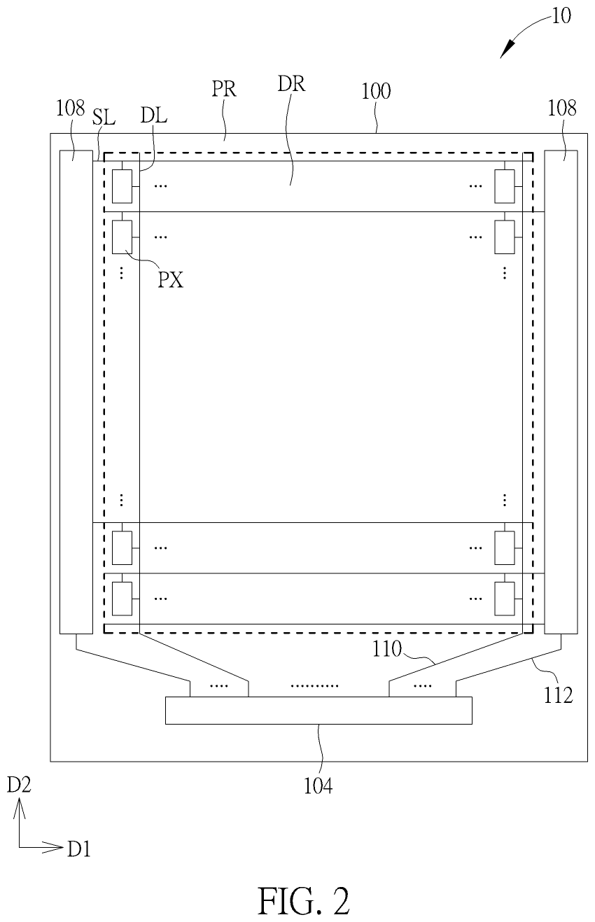

Referring to FIG. 1 and FIG. 2, FIG. 1 is a schematic diagram illustrating a top view of a touch portion of a touch display panel according to a first embodiment of the present invention, and FIG. 2 is a schematic diagram illustrating a top view of a display portion of the touch display panel according to the first embodiment of the present invention. For simplifying the drawings and for ease of comprehension, FIG. 1 omits some image displaying related components in the display region DR, and FIG. 2 omits some touch sensing related components in the display region DR. For example, a touch display panel 10 of this embodiment may be an in-cell liquid crystal touch display panel, but not limited thereto. As shown in FIG. 1, a substrate 100 of the touch display panel 10 includes a display region DR and a peripheral region PR disposed by at least one side of the display region DR. In this embodiment, the peripheral region PR surrounds the display region DR, but it is not limited thereto. The substrate 100 may be a rigid substrate, such as a glass substrate, plastic substrate, quartz substrate, or sapphire substrate, or the substrate 100 may be a flexible substrate including materials such as polyimide (PI) or polyethylene terephthalate (PET) for example, but not limited thereto. A plurality of touch electrodes 102 are disposed in the display region DR of the substrate 100, and the touch electrodes 102 are separated from each other. The touch electrodes 102 can be arranged into a plurality of columns and a plurality of rows, and the touch electrodes 102 can be arranged in the matrix manner, but not limited thereto. The touch electrode rows extend in a first direction D1, the touch electrode columns extend in a second direction D2, and the first direction D1 and the second direction D2 are not parallel. The first direction D1 is perpendicular to the second direction D2 in this embodiment, but not limited thereto. The arrangement or the number of the touch electrodes 102 may be different according to different designs of the touch display panel 10.

The touch display panel 10 includes a plurality of touch signal lines SSL disposed on the substrate 100. The touch signal lines SSL can substantially extend along the second direction D2, but not limited thereto. For example, the touch signal line SSL can extend in a curve fashion or a zigzag fashion along the second direction D2 in some embodiments. One of the touch signal lines SSL is electrically connected to one of the touch electrodes 102. Accordingly, each of the touch signal lines SSL is electrically connected to a corresponding touch electrode 102 to transmit and/or receive touch related signals. Each touch signal line SSL is electrically connected to the corresponding touch electrode 102 through a connecting structure 103. For example, one of the touch signal line SSL and one of the touch electrodes 102 can be electrically connected through a plug formed between the touch electrode signal line SSL and the touch electrode 102, but not limited thereto.

The touch display panel 10 includes an integrated circuit (IC) 104 disposed in the peripheral region PR and disposed on the substrate 100. The touch signal lines SSL are extended from the display region DR to the IC 104 disposed in the peripheral region PR via touch traces 106, and the touch signal lines SSL can be electrically connected to the IC 104. In this embodiment, the IC 104 can include the touch sensing circuit, and the IC 104 disposed on the substrate 100 can be a chip or system on glass (SOG), but not limited thereto. In some embodiments, the IC 104 can be a chip disposed on the flexible or rigid circuit board which can be further electrically connected to the touch signal lines SSL or other signal lines on the substrate 100. In this embodiment, the IC 104 can transmit and/or receive touch sensing signals, but not limited thereto.

As shown in FIG. 2, a plurality of scan lines SL and a plurality of data lines DL are disposed on the substrate 100, the scan lines SL can extend along the first direction D1, and the data lines DL can extend along the second direction D2, but not limited thereto. The data lines DL cross the scan lines SL to define a plurality of pixels PX in the display region DR, and the pixels PX may be arranged in the matrix manner for example, but not limited thereto. Each of the pixels PX can emit a light with the corresponding color, thereby enabling the display region DR of the touch display panel 10 to display an image. In this embodiment, each of the touch electrodes 102 in FIG. 1 may be formed by common electrodes of the corresponding pixels PX (or sub-pixels) in FIG. 2, and these common electrodes are electrically connected with each other. Therefore, one of the touch electrodes 102 includes a plurality of common electrodes and corresponds to a plurality of pixels PX. Accordingly, the touch electrodes 102 in this embodiment can be used as common electrodes during a display period of the touch display panel 10, and can be used to sense the touch position of the user during a touch sensing period of the touch display panel 10, but is not limited thereto. The common electrodes corresponding to different touch electrodes are separated.

In this embodiment, the data lines DL extend from the display region DR to the IC 104 disposed in the peripheral region PR through data traces 110, and the data lines DL can be electrically connected to the IC 104. In this embodiment, the IC 104 further includes a source driver circuit, but not limited thereto. In addition, the touch display panel 10 further includes at least one gate driver circuit 108 disposed on the substrate 100 and in the peripheral region PR. The gate driver circuit 108 is electrically connected to the IC 104 and can be used to drive the touch display panel 10. For example, the touch display panel 10 of this embodiment includes two gate driver circuits 108, the gate driver circuits 108 are respectively disposed on two sides of the display region DR in the first direction D1, and the IC 104 is disposed on one side of the display region DR in the second direction D2. The numbers and positions of the gate drive circuits 108 and the IC 104 are not limited to the above description.

In this embodiment, each of the scan lines SL is electrically connected to at least one gate driver circuit 108. As shown in FIG. 2, in two adjacent scan lines SL, one of the scan lines SL can be electrically connected to the gate driver circuit 108 disposed on the left side of the display region DR, and the other one of the scan lines SL can be electrically connected to the gate driver circuit 108 disposed on the right side of the display region DR, but not limited thereto. The IC 104 can output data signals to the data lines DL and output control signals to the gate driver circuits 108, but not limited thereto. In some embodiments, the control signals of the gate driver circuits 108 may be provided by other control chips. In addition, in this embodiment, the gate driver circuits 108 may be the gate driver on array (GOA) circuit structures, but not limited thereto. In some embodiments, the gate driver circuits 108 can be a chip, and the chip can be disposed on the substrate 100 or disposed on the flexible or rigid circuit board which is electrically connected to the connecting pads on the substrate 100, and the connecting pads can be electrically connected to the corresponding scan lines SL. For example, the gate driver circuits 108 can include a plurality of control signal lines (such as clock signal lines, initial signal lines, and ending signal lines). The control signal lines can be electrically connected to the IC 104 via traces 112, and the IC 104 can transmit the control signals (such as clock signals, initial signals, and ending signals) to the gate driver circuits 108.

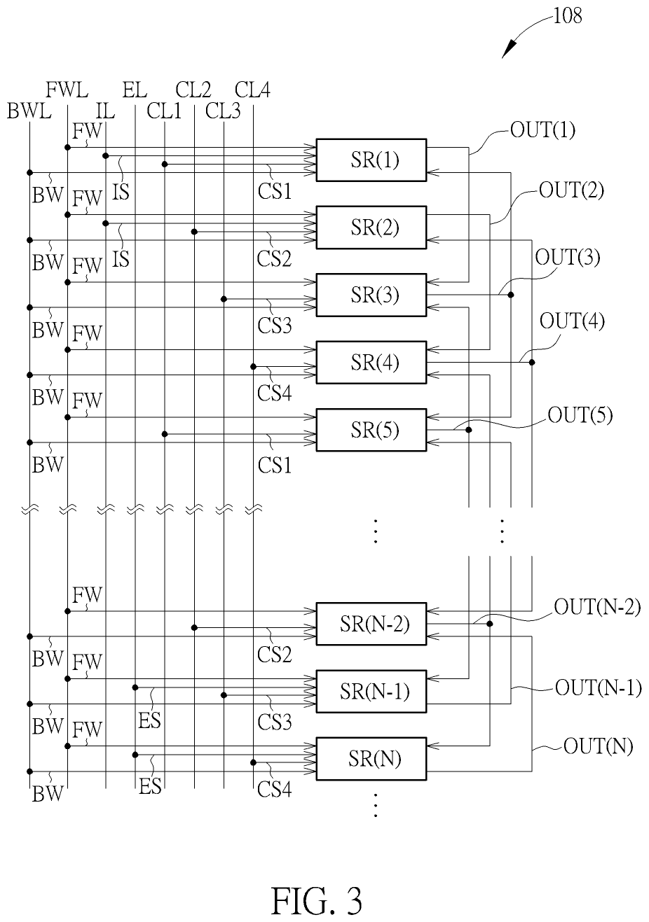

Referring to FIG. 3, it is a schematic diagram illustrating a gate driver circuit according to the first embodiment of the present invention. One of the gate driver circuits 108 in FIG. 1 or FIG. 2 is taken as an example, the gate driver circuit 108 includes clock signal lines CL1-CL4, an initial signal line IL, an ending signal line EL, a forward input signal line FWL, a backward input signal line BWL, and a first-level shift register SR(1) to a nth-level shift register SR(N), wherein N is a positive integer greater than or equal to 5, but not limited thereto. The first-level shift register SR(1) to the nth-level shift register SR(N) in this embodiment may be the gate driver on array (GOA) circuit structure, but not limited thereto. The clock signal lines CL1 to CL4 provide clock signals CS1-CS4 to the corresponding shift registers SR(1)-SR(N). Furthermore, N may be a multiple of 4, and the clock signal line CL1 provides the clock signal CS1 to the first-level shift register SR(1), the fifth-level shift register SR(5) . . . and the (N−3)th-level shift register SR(N−3), the clock signal line CL2 provides the clock signal CS2 to the second-level shift register SR(2), the sixth-level shift register SR(6) . . . and the (N−2)th-level shift register SR(N−2), the clock signal line CL3 provides the clock signal CS3 to the third-level shift register SR(3), the seventh-level shift register SR(7) . . . and the (N−1)th-level shift register SR(N−1), and the clock signal line CL4 provides the clock signal CS4 to the fourth-level shift register SR(4), the eighth-level shift register SR(8) . . . and the Nth-level shift register SR(N). The number of the clock signal lines of the present invention is not limited to 4.

In addition, each of the shift registers receives a forward input signal FW and a backward input signal BW. For example, the forward input signal line FWL and the backward signal line BWL respectively provide the forward input signal FW and the backward input signal BW to the first-level shift register SR(1) to the Nth-level shift register SR(N). The initial signal line IL provides an initial signal IS to the first-level shift register SR(1) and the second-level shift register SR(2), and the ending signal line EL provides an ending signal ES to the (N−1)th-level shift register SR(N−1) and the Nth-level shift register SR(N). The clock signal lines CL1-CL4, the initial signal line IL, the ending signal line EL, the forward input signal line FWL, and the backward input signal line BWL may be coupled to one or more than one chip. That is, the clock signals CS1-CS4, the initial signal IS, the ending signal ES, the forward input signal FW, and the backward input signal BW may be provided by this one or more than one chip, such as a driving chip and/or a timing control chips and so on, but not limited thereto.

In addition, the first-level shift register SR(1) to the Nth-level shift register SR(N) respectively produce a first-level scan signal OUT(1) to a Nth-level scan signal OUT(N), and the scan signals OUT(1)-OUT(N) may be respectively output to the corresponding scan lines SL, and the pixels PX electrically connected to the shift registers are driven through the scan lines SL. The first-level scan signal OUT(1) and the second-level scan signal OUT(2) are respectively input to the third-level shift register SR(3) and the fourth-level shift register SR(4), the (N−1)th-level scan signal OUT(N−1) and the Nth-level scan signal OUT(N) are respectively input to the (N−3)th-level shift register SR(N−3) and the (N−2)th-level shift register SR(N−2), and each of the scan signals from the third-level scan signal OUT(3) to the (N−2)th-level scan signal OUT(N) is input to the shift register that is two levels greater than or two levels less than its own level. For example, the third-level scan signal OUT(3) is input to the first-level shift register SR(1) and the fifth-level shift register SR(5).

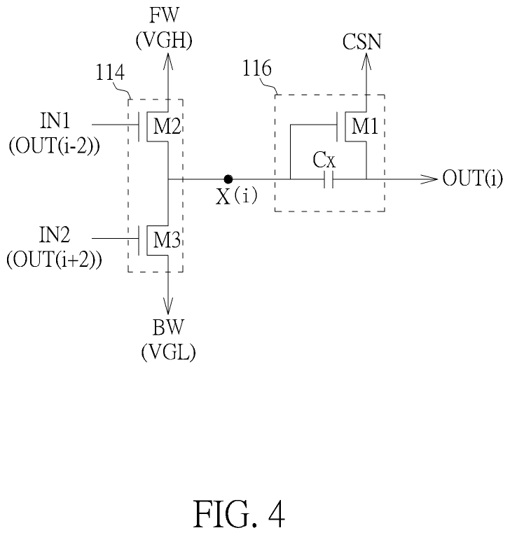

Referring to FIG. 4, it is an equivalent circuit diagram of an ith-level shift register in the gate driver circuit shown in FIG. 3. As shown in FIG. 4, an ith-level (wherein i is a positive integer from 1 to N) shift register SR(i) includes a precharge unit 114 and a pull-up unit 116, the precharge unit 114 and one end of the pull-up unit 116 are coupled to a node X(i), and another end of the pull-up unit 116 can output the ith-level scan signal OUT(i) to the corresponding scan line SL. The precharge unit 114 receives a first input signal IN1 and a second input signal IN2, and the precharge unit 114 controls the voltage level of the node X(i) according to the first input signal IN1 and a second input signal IN2. The precharge unit 114 includes thin film transistors M2, M3. In this embodiment, the gate driver circuit 108 is a two-way scanning driver circuit, and in the shift registers SR(1)-SR(N), a control end of the thin film transistor M2 receives the first input signal IN1, a first end of the thin film transistor M2 receives the forward input signal FW, and a second end of the thin film transistor M2 is coupled to the node X(i). A control end of the thin film transistor M3 receives the second input signal IN2, a first end of the thin film transistor M3 receives the backward input signal BW, and a second end of the thin film transistor M3 is coupled to a second end of the second thin film transistor M2. The forward input signal FW and the backward input signal BW have reverse phases in the display period of the touch display panel, that is, when one of the forward input signal FW and the backward input signal BW has a high voltage level, then another one would have a low voltage level. The term “reverse phases” in the present invention can mean that one of signals has a voltage level greater than a specific voltage level, and the other one of signals has a voltage level less than the specific voltage level.

In addition, in the embodiment that the gate driver circuit 108 is a one-way scanning driver circuit, the first end of the thin film transistor M2 receives a high voltage level, and the first end of the thin film transistor M3 receives a low voltage level. In the gate driver circuit shown in FIG. 3, the forward input signal line FWL and the backward input signal line BWL may respectively be replaced by a high voltage level line and a low voltage level line, and the remaining portion is similar to the above description. For example, the “high voltage level” may be a gate high voltage (VGH), and the “low voltage level” may be a gate low voltage (VGL). In the present invention, the “control end”, “first end”, and “second end” of the thin film transistor may respectively represent the gate electrode, the source electrode, and the drain electrode of a thin film transistor, or may respectively represent the gate electrode, the drain electrode, and the source electrode of a thin film transistor.

If the shift register SR(i) is a first-level shift register or a second-level shift register (that is, i is 1 or 2), then the first input signal IN1 is the initial signal IS, and the second input signal IN2 is a (i+2)th-level scan signal OUT(i+2) output by the (i+2)th-level shift register SR(i+2) (that is, the third-level scan signal OUT(3) or the fourth-level scan signal OUT(4)). If the shift register SR(i) is any one of the shift registers from the third-level shift register to the (N−2)th-level shift register (that is, i is any one of integers from 3 to (N−2)), then the first input signal IN1 is the (i−2)th-level scan signal OUT(i−2) output by the (i−2)th-level shift register SR(i−2), and the second input signal IN2 is the (i+2)th-level scan signal OUT(i+2) output by the (i+2)th-level shift register SR(i+2). If the shift register SR(i) is a (N−1)th-level shift register or a (N)th-level shift register (that is, i is (N−1) or N), then the first input signal IN1 is the (i−2)th-level scan signal OUT(i−2) output by the (i−2)th-level shift register SR(i−2) (that is, the (N−3)th-level scan signal OUT(N−3) or the (N−2)th-level scan signal (N−2)), and the second input signal IN2 is the ending signal ES.

It should be noted that, each shift register SR(i) outputs a scan signal OUT(i) to the touch display panel 10 according to the forward input signal FW and the backward input signal BW. When the gate driver circuit 108 is in a forward scanning mode, the forward input signal FW has high voltage level and the backward input signal BW has low voltage level; when the gate driver circuit 108 is in a backward scanning mode, the forward input signal FW has low voltage level and the backward input signal BW has high voltage level.

The pull-up unit 116 is coupled to the precharge unit 114 at the node X(i), the pull-up unit 116 receives a clock signal CSN, and the scan signal OUT(i) is output according to the voltage level of the node X(i) and the clock signal CSN, and the clock signal CSN can be any one of the clock signals CS1-CS4. In the embodiment where N is a multiple of 4, if i is 1, 5 . . . (N−3), then the clock signal CSN is the clock signal CS1; if i is 2, 6 . . . (N−2), then the clock signal CSN is the clock signal CS2; if i is 3, 7 . . . (N−1), then the clock signal CSN is the clock signal CS3; if i is 4, 8 . . . N, then the clock signal CSN is the clock signal CS4. The pull-up unit 116 includes a thin film transistor M1 and a capacitance Cx. A control end of the thin film transistor M1 receives a precharge signal, a first end of the thin film transistor M1 receives the clock signal CSN, and a second end of the thin film transistor M1 outputs the scan signal OUT(i). A first end of the capacitance Cx is coupled to the control end of the thin film transistor M1, and a second end of the capacitance Cx is coupled to the second end of the thin film transistor M1.

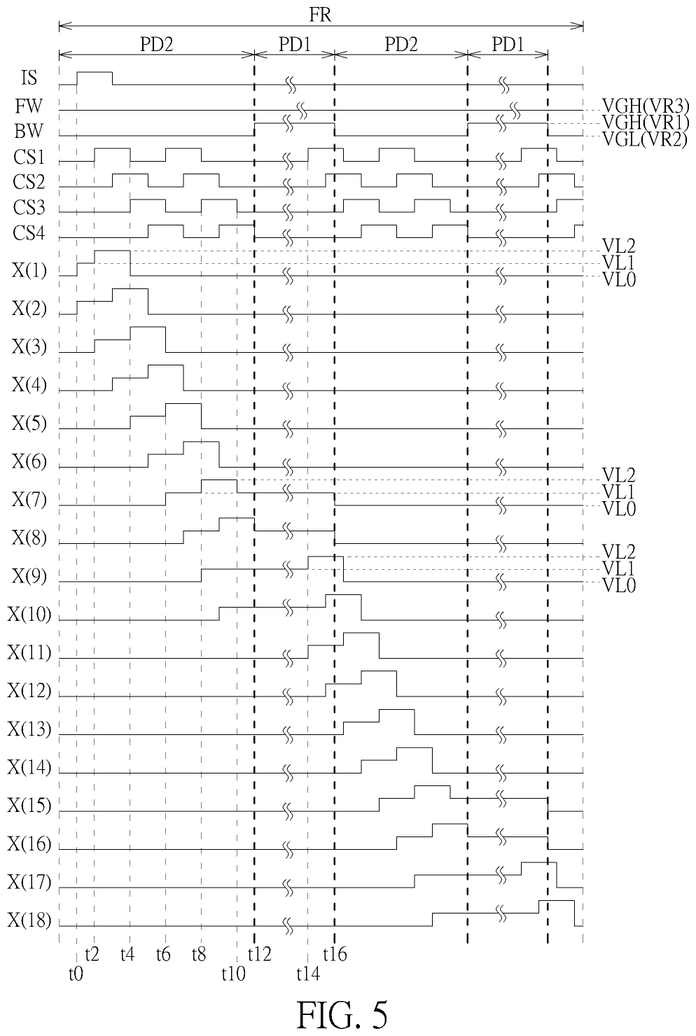

FIG. 5 is a timing diagram of the gate driver circuit of FIG. 3 in a forward scanning mode. In order to make the drawing more simplified and easy to understand, FIG. 5 shows a portion of the operation of signals in one frame time FR, and FIG. 5 shows the operation of a portion of signals related to the first-level shift register SR(1) to the eighteenth-level shift register SR(18). As shown in FIG. 5, at least one first period PD1 and at least one second period PD2 are included in one frame time FR, the touch display panel 10 performs touch sensing in the first period PD1, and the touch display panel 10 is driven to display in the second period PD2. For example, the frame time FR may include a plurality of first periods PD1 and a plurality of second periods PD2 arranged alternately, but not limited thereto. In addition, the gate driver circuit 108 of this embodiment can be operated in the forward scanning mode, for example, the forward input signal FW can have high voltage level (such as VGH) and the backward input signal BW can have low voltage level (such as VGL) in the second period PD2. That is, the forward input signal FW and the backward input signal BW provided to the shift register SR(i) have reverse phases (e.g., VGL and VGH) in the second period PD2, but not limited thereto.

Taking the node X(1) of the first-level shift register SR(1) and the node X(3) of the third-level shift register SR(3) in FIG. 5 as an example (referring to FIG. 3 and FIG. 4 together), when the initial signal IS rises from low voltage level to high voltage level at a time t0, the voltage level of the node X(1) changes from a reference voltage level VL0 to a first voltage level VL1 according to the initial signal IS (the first input signal IN1). At a time t2, the clock signal CS1 rises from low voltage level to high voltage level, and the voltage level of the node X(1) changes from the first voltage level VL1 to a second voltage level VL2 according to the clock signal CS1. At this time, the first-level shift register SR(1) outputs the first-level scan signal OUT(1) to the corresponding scan line SL according to the voltage level of the node X(1) and the clock signal CS1, and the voltage level of the node X(3) rises from the reference voltage level VL0 to the first voltage level VL1 according to the first-level scan signal OUT(1). At a time t4, the clock signal CS1 drops from high voltage level to low voltage level, and the clock signal CS3 rises from low voltage level to high voltage level. At this time, the voltage level of the node X(3) rises from the first voltage level VL1 to the second voltage level VL2 according to the clock signal CS3, causing the third-level shift register SR(3) to output the third-level scan signal OUT(3) to the corresponding scan line SL. Meanwhile, the initial signal IS serving as the first input signal IN1 of the first-level shift register SR(1) has dropped back to low voltage level, and the third-level scan signal OUT(3) serving as the second input signal IN2 is input to the first-level shift register SR(1), so that the voltage level of the node X(1) is changed from the second voltage level VL2 to the reference voltage level VL0, and the first-level shift register SR(1) stops outputting the first-level scan signal OUT(1) to the corresponding scan line SL. The period between the time t0 and the time t4 can be regarded as the time when the first-level shift register SR(1) outputs the first-level scan signal OUT(1) to drive the corresponding scan line SL. The second voltage level VL2 may be greater than the first voltage level VL1 and the reference voltage level VL0, and the first voltage level VL1 may be greater than the reference voltage level VL0, but not limited thereto. The above operation method of the shift registers can be applied to the shift registers SR(1)-SR(6) and SR(11)-SR(14) in FIG. 5. The above mentioned shift registers (SR(1)-SR(6) and SR(11)-SR(14)) are not the shift registers which the nodes X(i) have the second voltage level VL2 in the first period PD1 (such as SR(9), SR(10), SR(17), and SR(18) in FIG. 5) and the shift registers that are two levels less than these shift registers (such as SR(7), SR(8), SR(15), and SR(16) in FIG. 5), but not limited thereto.

In another aspect, the forward input signal FW and the backward input signal BW provided to the shift register SR(i) are in phase in the first period PD1. As shown in FIG. 5, the forward input signal FW and the backward input signal BW provided to the shift register SR(i) are in phase at least twice in one frame time FR in this embodiment, but not limited thereto. In some embodiment, the forward input signal FW and the backward input signal BW may be in phase three times or more than three times in one frame time FR. In some embodiments, the forward input signal FW and the backward input signal BW may be in phase once in a frame time FR. Specifically, the backward input signal BW has a first reference voltage level VR1 in the first period PD1 and a second reference voltage level VR2 in the second period PD2, and the first reference voltage level VR1 is different from the second reference voltage level VR2. The first reference voltage level VR1 may be greater than the second reference voltage level VR2, for example, the first reference voltage level VR1 may be VGH and the second reference voltage level VR2 may be VGL, but not limited thereto. Additionally, the forward input signal FW has a third reference voltage level VR3 (e.g., VGH) throughout the frame time FR. Therefore, in the first period PD1, the first reference voltage level VR1 of the backward input signal BW and the third reference voltage level VR3 of the forward input signal FW can be identical, but not limited thereto. The term “in phase” in the present invention can mean that the voltage levels of different signals are both greater than or less than a specific voltage level.

Taking the node X(7) of the seventh-level shift register SR(7) and the node X(9) of the ninth-level shift register SR(9) in FIG. 5 as an example (referring to FIG. 3 and FIG. 4 together), when the voltage level of the node X(5) changes from the first voltage level VL1 to the second voltage level VL2 at a time t6 and the fifth-level shift register SR(5) starts outputting the fifth-level scan signal OUT(5), the voltage level of the node X(7) also changes from the reference voltage level VL0 to the first voltage level VL1 according to the fifth-level scan signal OUT(5) (i.e., the first input signal IN1). At a time t8, the clock signal CS3 rises from the low voltage level to the high voltage level, and the voltage level of the node X(7) changes from the first voltage level VL1 to the second voltage level VL2 according to the clock signal CS3. At this time, the seventh-level shift register SR(7) outputs the seventh-level scan signal OUT(7) to the corresponding scan line SL according to the voltage level of the node X(7) and the clock signal CS3, and the voltage level of the node X(9) rises from the reference voltage level VL0 to the first voltage level VL1 according to the seventh-level scan signal OUT(7). At a time point t10, the clock signal CS3 drops from high voltage level to low voltage level, and the voltage level of the node X(7) changes from the second voltage level VL2 to the first voltage level VL1, and the seventh-level shift register SR(7) stops outputting the seventh-level scan signal OUT(7) to the corresponding scan line SL. Subsequently, at a time point t12, the second period PD2 (display period) is ended and the first period PD1 (touch period) is started. Since the first period PD1 is inserted between two second periods PD2, the node X(7) and the node X(9) are held at high voltage level for a long time (e.g., hundreds of microseconds) compared to the node X(1) and the node X(3). Referring to FIG. 4 and FIG. 5, the forward input signal FW and the reverse input signal BW are in phase after the first period PD1 is started. The backward input signal BW may for example be raised to be identical to the forward input signal FW, and the leakage current of the thin film transistor M3 may be reduced because the backward input signal BW and the forward input signal FW have the same voltage level, so that the voltage levels of the node X(7) and the node X(9) are not affected by the leakage current of the thin film transistor M3 in the first period PD1, and the voltage levels of the node X(7) and the node X(9) can be held at the first potential VL1 for a long time.

Next, at a time t14 in the first period PD1, the clock signal CS1 rises from low voltage level to high voltage level. At this time, the voltage level of the node X(9) rises from the first voltage level VL1 to the second voltage level VL2 according to the clock signal CS1, causing the ninth-level shift register SR(9) to output the ninth-level scan signal OUT(9) to the seventh-level shift register SR(7) to turn on the thin film transistor M3 of the seventh-level shift register SR(7). Although the thin film transistor M3 of the seventh-level shift register SR(7) is turned on, since the forward input signal FW and the backward input signal BW are in phase and the backward input signal BW may have high voltage level, the voltage level of the node X(7) can still be held at the first voltage level VL1. At a time t16, the second period PD2 (display period) is ended and the first period PD1 (touch period) is started, and the backward input signal BW is changed from the first reference voltage level VR1 to the second reference voltage level VR2, that is, the forward input signal FW and the backward input signal BW are changed from being in phase to having reverse phases. Therefore, electric charges of the node X(7) can flow out through the thin film transistor M3 of the seventh-level shift register SR(7), so that the voltage level of the node X(7) can be changed from the first voltage level VL1 to the reference voltage level VL0. In this embodiment, at a time between the time t14 and the time t16, the node X(7) has the first voltage level VL1, and the node X(9) of the ninth-level shift register SR(9) has the second potential VL2. Additionally, in some embodiments, although the node X(9) has risen from the first voltage level VL1 to the second voltage level VL2, the ninth-level scan signal OUT(9) can be blocked by the IC from outputting to the corresponding scan line SL in the first period PD1 (touch period), the ninth-level scan signal OUT(9) can be output to the corresponding scan line SL after the second period PD2 (display period) is started, and the touch sensing can be avoided from being interfered by the display signals in the first period PD1, but not limited thereto. The above operation method of the shift registers can be applied to the shift registers SR(7)-SR(10) and SR(15)-SR(18) in FIG. 5, that is, the shift registers in which the nodes X(i) have the second voltage level VL2 in the first period PD1 and the shift registers that are two levels less than these shift registers, but not limited thereto.

For the conventional gate driver circuit 108, the node X(9) is affected by the leakage current of the thin film transistor M3 after the first period PD1 is started. Since the thin film transistor M3 is affected by the leakage current for a long time (possibly hundreds of microseconds) in the first period PD1, the decrease of the voltage level of the node X(9) with time becomes obvious. Moreover, the second voltage level VL2 of the node X(9) related to the ninth-level scan signal OUT(9) is also affected, thereby distorting the ninth-level scan signal OUT(9) and causing the display image to have horizontal stripes. However, in this embodiment, the forward input signal FW and the backward input signal BW can be in phase in the first period PD1 by raising the voltage level of the backward input signal BW in the first period PD1, the leakage current of the thin film transistor M3 can be reduced and the voltage level of the node X(9) can be maintained, and the distortion of the scan signal OUT(9) and the phenomenon of horizontal stripes in the display image can be avoided. In addition, the shift registers SR(10), SR(17), and SR(18) in FIG. 5 (i.e., the shift registers with the nodes X(i) having the second voltage level VL2 in the first period PD1) can also have the above effects. Furthermore, the gate driver circuits 108 on the left and right sides of the display region DR in FIG. 1 or FIG. 2 can have the above-mentioned features and effects, but not limited thereto. According to the above description, a driving method of a touch display panel 10 is provided in this embodiment, the driving method includes: providing a gate driver circuit 108 including a plurality of shift registers SR(i), wherein each of the shift registers SR(i) receives a forward input signal FW and a backward input signal BW, and the shift registers SR(i) sequentially output a plurality of scan signals OUT(i) to the touch display panel 10 according to the forward input signal FW and the backward input signal BW, wherein the forward input signal FW and the backward input signal BW provided to the shift registers SR(i) are set to be in phase at least twice in a frame time FR. The effects described in the above description can be achieved by this driving method.

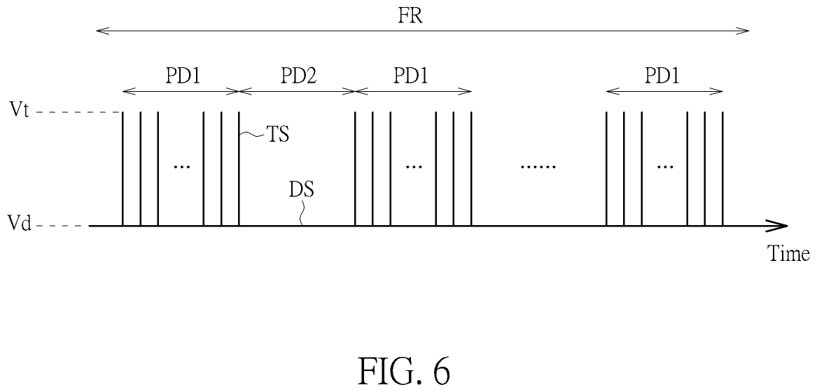

Referring to FIG. 6, it is a schematic diagram of signals received by a common electrode according to the first embodiment of the present invention. The start or end of the first period PD1 (touch period) of this embodiment can be determined, for example, by signals received by a common electrode. For example, the common electrode may receive a plurality of sensing signals TS to sense the touch of object in each of the first periods PD1, and the common electrode may receive a display signal DS to display images in each of the second periods PD2. The voltage level of the sensing signal TS is different from that of the display signal DS. For example, the sensing signal TS may have a sensing voltage level Vt, the display signal DS may have a display reference voltage level Vd, and the sensing voltage level Vt may be greater than the display reference voltage level Vd, but not limited thereto. Therefore, the first period PD1 and the second period PD2 can be distinguished according to the change in signals or voltage levels received by the common electrode within a frame time FR. However, the method for distinguishing the first period PD1 and the second period PD2 is not limited to the above description. In some embodiments, the first period PD1 and the second period PD2 may be distinguished according to the change in the voltage level of the signal output and/or received by the touch electrode signal line SSL. In some embodiments, the first period PD1 and the second period PD2 may be distinguished according to the change in the voltage level of the signal output and/or received by the scan line SL or the data line DL. In addition, in some embodiments, the clock signals CS1-CS4 may also be used for determining the time at which the first period PD1 is started. For example, as shown in FIG. 5, the clock signals CS1-CS4 are sequentially and periodically raised from low voltage level to high voltage level and then lowered from high voltage level to low voltage level in the second period PD2. The clock signals CS1-CS4 are all held at low voltage level after the first period PD1 is started, and the clock signals CS1-CS4 start to change sequentially and periodically again in the end of the first period PD1 or after the start of the next second period PD2. Therefore, the time at which the first period PD1 starts can be determined by observing the time at which the clock signals CS1-CS4 stop changing sequentially and periodically. In the frame time FR, the first period PD1 may start first and followed by the second period PD2, or the second period PD2 may start first and followed by the first period PD1.

The gate driver circuit of the present invention is not limited to the aforementioned embodiment. The following description continues to detail other embodiments. To simplify the description and show the difference between other embodiments and the above-mentioned embodiment, identical components in each of the following embodiments are marked with identical symbols, and the identical features will not be redundantly described.

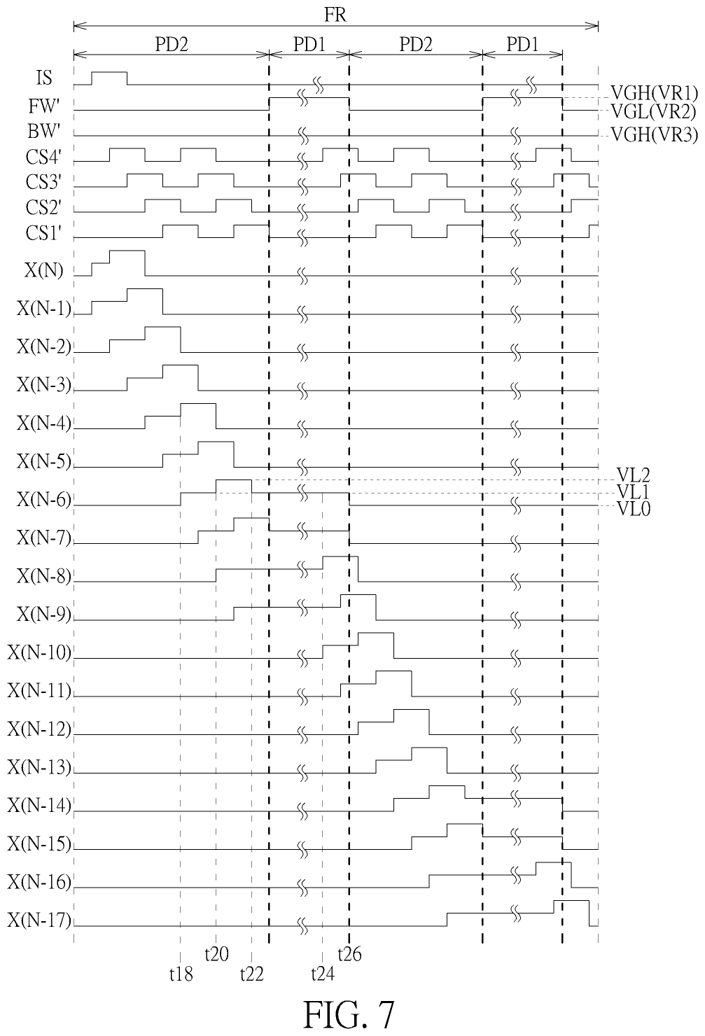

Referring to FIG. 7, it is a timing diagram of the gate driver circuit in a backward scanning mode according to a second embodiment of the present invention. Different from the first embodiment, the gate driver circuit 108 of this embodiment is in the backward scanning mode. For example, the forward input signal FW′ has low voltage level and the backward input signal BW′ has high voltage level in the second period PD2. Specifically, the backward input signal BW′ has the third reference voltage level VR3 in both the first period PD1 and the second period PD2, and the forward input signal FW′ has the first reference voltage level VR1 in the first period PD1 and the second reference voltage level VR2 in the second period PD2. The first reference voltage level VR1 and the third reference voltage level VR3 may be high voltage levels (e.g., VGH), and the second reference voltage level VR2 may be low voltage level (e.g., VGL), but not limited thereto. In this embodiment, the initial signal IS is input to the (N−1)th-level shift register SR(N−1) and the Nth-level shift register SR(N), and the ending signal ES (not shown) is input to the first-level shift register SR(1) and the second-level shift register SR(2). Therefore, the initial signal IS provided to the first-level shift register SR(1) and the second-level shift register SR(2) through the initial signal line IL in FIG. 3 is replaced by the ending signal ES in this embodiment, and the ending signal ES provided to the (N−1)th-level shift register SR(N−1) and the Nth-level shift register SR(N) through the ending signal line EL is replaced by the initial signal IS in this embodiment. In addition, the input sequence of the clock signals CS1′-CS4′ is also adjusted in the backward scanning mode, for example, the clock signals CS1′-CS4′ are sequentially input into the corresponding shift registers SR(i) from the clock signal CS4′ to the clock signal CS1′. Therefore, the Nth-level scan signal OUT(N) to the first-level scan signal OUT(1) can be respectively generated from the Nth-level shift register SR(N) to the first-level shift register SR(1), the scan signals OUT(N)-OUT(1) can be respectively output to the corresponding scan lines SL, and the pixels PX electrically connected to the shift registers can be driven by the scan lines SL.

Different from the first embodiment, the (i−2)th-level scan signal OUT(i−2) received by the control end of the thin film transistor M2 of the shift register SR(i) is the second input signal IN2 in this embodiment, and the (i+2)th-level scan signal OUT(i+2) received by the control end of the thin film transistor M3 is the first input signal IN1 in this embodiment. Specifically, if the shift register SR(i) is the Nth-level shift register or (N−1)th-level shift register (i.e., i is N or (N−1)), the signal input to the control end of the thin film transistor M3 (i.e., the first input signal IN1) is the initial signal IS, and the signal input to the control end of the thin film transistor M2 (i.e., the second input signal IN2) is the scan signal OUT (i−2) output from the (i−2)th-level shift register SR(i−2). If the shift register SR(i) is any one of the shift registers from the (N−2)th-level shift register to the third-level shift register (i.e., i is any positive integer from (N−2) to 3), the signal input to the control end of the thin film transistor M3 (i.e., the first input signal IN1) is the (i+2)th-level scan signal OUT(i+2) output from the (i+2)th-level shift register SR(i+2), and the signal input to the control end of the thin film transistor M2 (i.e., the second input signal IN2) is the (i−2)th-level scan signal OUT(i−2) output by the (i−2)th-level shift register SR(i−2). If the shift register SR(i) is the first-level shift register or second-level shift register (i.e., i is 1 or 2), the signal input to the control end of the thin film transistor M3 (i.e., the first input signal IN1) is the (i+2)th-level scan signal OUT(i+2) output from the (i+2)th-level shift register SR(i+2), and the signal input to the control end of the thin film transistor M2 (i.e., the second input signal IN2) is the ending signal ES.

In another aspect, the node X(N−6) of the (N−6)th-level shift register SR(N−6) and the node X(N−8) of the (N−8)th-level shift register SR(N−8) in FIG. 7 are taken as an example. At a time t18 before the first period PD1, the clock signal CS4′ rises from low voltage level to high voltage level, and the voltage level of the node X(N−4) changes from the first voltage level VL1 to the second voltage level VL2 according to the clock signal CS4′. At this time, the (N−4)th-level shift register SR(N−4) outputs the (N−4)th-level scan signal OUT(N−4) to the (N−6)th-level shift register SR(N−6) according to the voltage level of the node X(N−4) and the clock signal CS4′. The voltage level of the node X(N−6) is changed from the reference voltage level VL0 to the first voltage level VL1 according to the first input signal IN1 (i.e., the (N−4)th-level scan signal OUT(N−4)) before the first period PD1 (e.g., at the time t18). Next, at a time t20, the clock signal CS2′ rises from low voltage level to high voltage level, and the voltage level of the node X(N−6) changes from the first voltage level VL1 to the second voltage level VL2 according to the clock signal CS2′. At this time, the (N−6)th-level shift register SR(N−6) outputs the (N−6)th-level scan signal OUT(N−6) to the (N−8)th-level shift register SR(N−8) according to the voltage level of the node X(N−6) and the clock signal CS2′, and the node X(N−8) rises from the reference voltage level VL0 to the first voltage level VL1 due to the (N−6)th-level scan signal OUT(N−6). At a time t22, the clock signal CS2′ drops from high voltage level to low voltage level, and the voltage level of the node X(N−6) changes from the second voltage level VL2 to the first voltage level VL1.

Next, the first period PD1 is started. Since the forward input signal FW′ and the backward input signal BW′ are in phase in the first period PD1, the voltage level of the node X(N−6) and the node X(N−8) can be prevented from being affected by the leakage current of the thin film transistor M2, and the voltage level can be held at the first potential VL1. Then, at a time t24, the voltage level of the node X(N−8) rises from the first voltage level VL1 to the second voltage level VL2 according to the clock signal CS4′, causing the (N−8)th-level shift register SR(N−8) to output the (N−8)th-level scan signal OUT(N−8). Next, at a time t26, the first period PD1 is ended, the forward input signal FW′ and the backward input signal BW′ are changed from being in phase to having reverse phases, and the voltage level of the node X(N−6) is also changed from the first voltage level VL1 to the reference voltage level VL0. Therefore, at a time between the time t24 and the time t26, the node X(N−6) has the first voltage level VL1, and the node X(N−8) has the second voltage level VL2. Since the voltage level of the forward input signal FW′ is increased in the first period PD1, the forward input signal FW′ and the backward input signal BW′ are in phase, the high voltage level of the forward input signal FW′ can reduce the leakage current of the thin film transistor M2 and reduce the influence of the leakage current of the thin film transistor M2 on voltage levels of the node X(N−6) and the node X(N−8), and the voltage levels of the node X(N−6) and the node X(N−8) can be maintained, thereby avoiding distortion of the (N−8)th-level scan signal OUT(N−8) and the phenomenon of horizontal stripes in the display image. In addition, the shift registers SR(N−9), SR(N−16), and SR(N−17) in FIG. 7 (i.e., the shift registers in which the nodes X(i) have the second voltage level VL2 in the first period PD1) can all have the above effects.

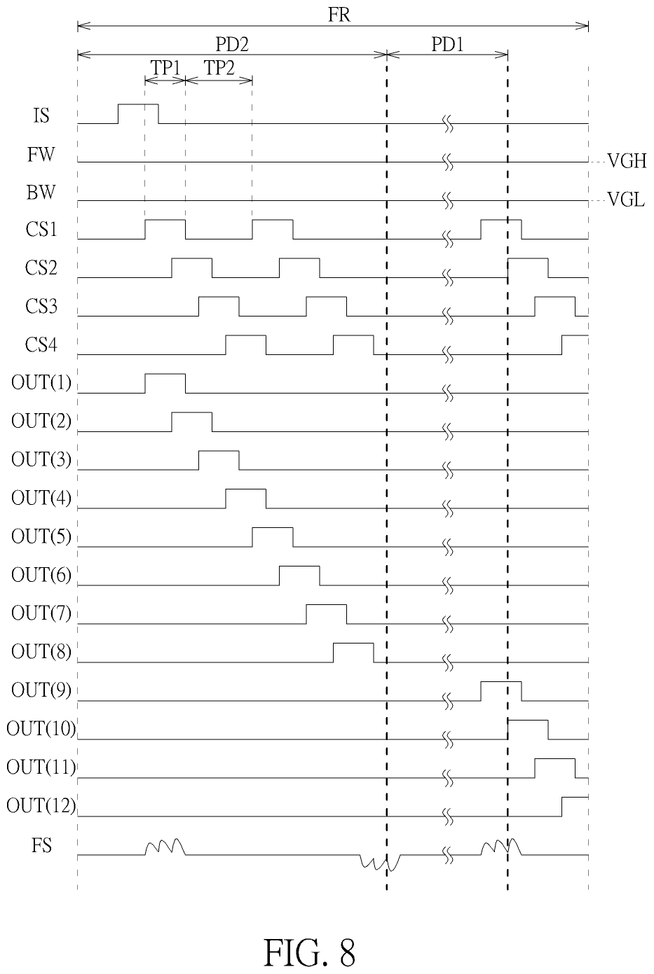

Referring to FIG. 8, it is a timing diagram of a gate driver circuit in a forward scanning mode according to a third embodiment of the present invention. Different from the above embodiments, the time durations of the clock signals CS1-CS4 having high voltage level and low voltage level are different in this embodiment. Taking the clock signal CS1 in FIG. 8 as an example, the clock signal CS1 has high voltage level in a time period TP1 and low voltage level in a time period TP2. The ratio of the time period TP1 and the time period TP2 can be 3:5, and the time period TP1 may include three units of time and the time period TP2 may include five units of time, but not limited thereto. The ratio of the time period TP1 and the time period TP2 may be greater than or equal to 3:5 and less than 1:1 (e.g., both the time period TP1 and the time period TP2 include four units of time). In addition, when the ratio of the time period TP1 to the time period TP2 is less than 3:5 (e.g., when the time period TP1 is less than three units of time), the charging efficiency of the thin film transistor in the shift register SR(i) may be affected. In the conventional touch display panel, the time durations of the clock signal having high voltage level and low voltage level are usually identical, for example, the time period TP1 and the time period TP2 may both include four units of time. However, the time period TP1 is shortened to include three units of time and the time period TP2 is extended to include five units of time when each period (the sum of the time period TP1 and the time period TP2) includes eight units of time in this embodiment, and the output time of the scan signal OUT(i) is shortened as the time period TP1 is shortened. Since the scan signal OUT(i) will cause other image display signals FS to have ripples and cause the display image to have horizontal stripes and reduce the display quality of the image, the ripples in the image display signal FS caused by the scan signal OUT(i) can be reduced by shortening the time period TP1 and shortening the output time of the scan signal OUT(i) in this embodiment, and the display quality of the image can be improved. In this embodiment, the image display signal FS may be, for example, a signal received by the common electrode, a signal received by the data line DL, or other display-related signals. but not limited thereto.

Specifically, the scan signal OUT(i) output in the beginning of the frame time FR will cause the other image display signals FS in the touch display panel 10 to have ripples, such as the scan signals OUT(1) and OUT(2) in FIG. 8. Similar to the beginning of the frame time FR, the scan signal OUT(i) output in the end of the frame time FR (not shown in FIG. 8) also causes the other image display signals FS in the touch display panel 10 to have ripples. In addition, the scan signals OUT(i) output in the beginning and the end of the touch period (i.e., the first period PD1) also cause the other image display signals FS in the touch display panel 10 to have ripples, such as the scan signals OUT(7) and OUT(8) corresponding to the beginning of the first period PD1, and the scan signals OUT(9) and OUT(10) corresponding to the end of the first period PD1 in FIG. 8. In this embodiment, the ripples of signals in different periods of time can be reduced by shortening the time period TP1 and shortening the output time of the scan signal OUT(i).

As shown in FIG. 8, one of the gate driver circuits 108 in this embodiment may be in the forward scanning mode, and the voltage level of the forward input signal FW may be greater than the voltage level of the backward input signal BW throughout the frame time FR. For example, the voltage level of the forward input signal FW may be VGH, and the voltage level of the backward input signal BW may be VGL, but not limited thereto. In addition, the other gate driver circuit 108 in this embodiment may be in the backward scanning mode, and the voltage level of the forward input signal FW may be less than the voltage level of the backward input signal BW throughout the frame time FR. For example, the voltage level of the forward input signal FW may be VGL, and the voltage level of the backward input signal BW may be VGH. However, the driving method of the gate driver circuits 108 is not limited to the above description.

To sum up, in the gate driver circuit and the driving method of the touch display panel of the present invention, the forward input signal and the backward input signal are set to be in phase in the touch period (i.e., the first period). For example, the forward input signal and the backward input signal are designed to have the identical voltage level. Therefore, the leakage current of the thin film transistor in the shift register can be reduced to avoid the distortion of the scan signal output by the shift register and the phenomenon that the display image has horizontal stripes, thereby improving the image display quality. In addition, the output time of the scan signal can be shortened by shortening the time duration of the clock signal having high voltage level, thereby reducing the phenomenon that the scan signal causes other image display signals to have ripples in the touch display panel.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A gate driver circuit used for driving a touch display panel, the gate driver circuit comprising:
a plurality of shift registers, wherein each of the shift registers receives a forward input signal and a backward input signal, and the shift registers sequentially output a plurality of scan signals to the touch display panel according to the forward input signal and the backward input signal,
wherein the forward input signal and the backward input signal provided to the shift registers are in phase at least twice in a frame time.

2. The gate driver circuit according to claim 1, wherein the touch display panel performs touch sensing in a first period of the frame time, and the forward input signal and the backward input signal provided to the shift registers are in phase.

3. The gate driver circuit according to claim 2, wherein the touch display panel is driven to display in a second period of the frame time, and the forward input signal and the backward input signal provided to the shift registers have reverse phases.

4. The gate driver circuit according to claim 3, wherein one of the forward input signal and the backward input signal has a first reference voltage level in the first period and a second reference voltage level in the second period, and the first reference voltage level and the second reference voltage level are different.

5. The gate driver circuit according to claim 4, wherein the first reference voltage level of the one of the forward input signal and the backward input signal is identical to a third reference voltage level of another one of the forward input signal and the backward input signal in the first period.

6. A driving method of a touch display panel, comprising:
providing a gate driver circuit comprising a plurality of shift registers, wherein each of the shift registers receives a forward input signal and a backward input signal, and the shift registers sequentially output a plurality of scan signals to the touch display panel according to the forward input signal and the backward input signal,
wherein the forward input signal and the backward input signal provided to the shift registers are set to be in phase at least twice in a frame time.

7. The driving method of the touch display panel according to claim 6, wherein the touch display panel performs touch sensing in a first period of the frame time, and the forward input signal and the backward input signal provided to the shift registers are in phase.

8. The driving method of the touch display panel according to claim 7, wherein the touch display panel is driven to display in a second period of the frame time, and the forward input signal and the backward input signal provided to the shift registers are set to have reverse phases.

9. The driving method of the touch display panel according to claim 8, wherein one of the forward input signal and the backward input signal has a first reference voltage level in the first period and a second reference voltage level in the second period, and the first reference voltage level and the second reference voltage level are different.

10. The driving method of the touch display panel according to claim 9, wherein the first reference voltage level of the one of the forward input signal and the backward input signal is identical to a third reference voltage level of another one of the forward input signal and the backward input signal in the first period.
